(19) United States
(12) Patent Application Publication
(10) Pub. No.: US 2018/0067367 A1
(43) Pub. Date: Mar. 8, 2018

(54) LTPS DISPLAY PANEL AND MANUFACTURE METHOD THEREOF

(71) Applicant: Wuhan China Star Optoelectronics Technology Co., Ltd., Wuhan City (CN)

(72) Inventors: Xiaojiang Yu, Wuhan City (CN); Wenzhi Le, Wuhan City (CN); Zhiyuan Shen, Wuhan City (CN)

(21) Appl. No.: 15/112,431

(22) PCT Filed: May 26, 2016
(86) PCT No.: PCT/CN2016/083565

§ 371 Date: Jul. 19, 2016

(30) Foreign Application Priority Data
Jan. 29, 2016 (CN) 201610063832.7

(51) Int. Cl. G02F 1/1362; H01L 27/12; G02F 1/1335

(52) U.S. Cl. CPC G02F 1/136209; G02F 1/133514; H01L 27/1222; H01L 27/1288

(57) ABSTRACT

The present invention provides a LTPS display panel and a manufacture method thereof. In the LTPS display panel, the edge of the back matrix (12) comprises a convex part (104) capable of ensuring that the light emitted from the pixel unit (22) of the array substrate (20) only penetrates through the color resist block (131/132/133) corresponding to the pixel unit (22) in the color film substrate (10), and no light leakage happens between adjacent pixel units and thus, can reduce the large view angle color washout to improve the display quality of the LTPS display panel. In the manufacture method of the LTPS display panel, one halftone mask process is employed to form the black matrix (12), and the edge of the back matrix (12) comprises a convex part (104) which can better shade the light leakage between adjacent pixel units as watching in the large view angle.

### FIELD OF THE INVENTION

The present invention relates to a display technology field, and more particularly to a LTPS display panel and a manufacture method thereof.

### BACKGROUND OF THE INVENTION

With the development of display technology, the flat panel device, such as Liquid Crystal Display (LCD) possesses advantages of high image quality, power saving, thin body and wide application scope. Thus, it has been widely applied in various consumer electrical products, such as mobile phone, television, personal digital assistant, digital camera, notebook, laptop, and becomes the major display device.

Most of the liquid crystal displays on the present market are back light type liquid crystal displays, which comprise a LTPS liquid crystal display panel and a back light module. The working principle of the liquid crystal display panel is to locate liquid crystal molecules between two parallel glass substrates, and a plurality of vertical and horizontal tiny electrical wires are between the two glass substrates. The light of back light module is reflected to generate images by applying driving voltages to control whether the liquid crystal molecules to be changed directions.

Generally, the liquid crystal display panel comprises a CF (Color Filter) substrate, a TFT (Thin Film Transistor) substrate, LC (Liquid Crystal) sandwiched between the CF substrate and TFT substrate and sealant. The formation process generally comprises: a forepart Array process (thin film, photo, etching and stripping), a middle Cell process (Lamination of the TFT substrate and the CF substrate) and a post module assembly process (Attachment of the driving IC and the printed circuit board). The forepart Array process is mainly to form the TFT substrate for controlling the movement of the liquid crystal molecules; the middle Cell process is mainly to add liquid crystal between the TFT substrate and the CF substrate; the post module assembly process is mainly the driving IC attachment and the integration of the printed circuit board. Thus, the liquid crystal molecules are driven to rotate and display pictures.

Low Temperature Poly Silicon (LTPS) is a kind of liquid crystal display technology which has been widely applied in the small, medium size electronic products. The electron mobility of the traditional amorphous silicon material is about 0.5-1.0 cm2/V·S but the electron mobility of the Low Temperature Poly Silicon can reach up to 30-300 cm2/V·S. Therefore, the Low Temperature Poly Silicon display has many advantages of high resolution, fast response speed and high aperture ratio. At present, the LTPS (Low Temperature Poly-Silicon) display panel has been widely used in the high end mobile phone, tablet. The IPHONE 6s phone, the LG G4phone, the Kindle Fire Hdx tablet all utilizes the LTPS display panels. However, the condition of large view angle color washout happens to some LTPS display panel. As the user watches LTPS display panel from the larger angle as tilted, it can be found that the panel display deviates the normal color levels.

As shown in FIG. 1, which is a structure diagram of a LTPS display panel according to prior art, the LTPS display panel comprises a color film substrate 100 and an array substrate 200. The color film substrate 100 comprises a first substrate 110, a black matrix 120 and a color resist layer 130 located on the first substrate 110, and a flat layer 140 located on the color resist layer 130; wherein the black matrix 120 comprises a plurality of black shading strips 121, of which the surfaces are even, and the color resist layer 130 comprises a plurality of color resist blocks 103; the array substrate 200 comprises a second substrate 210, and a plurality of pixel units 220 located on the second substrate 210 and located corresponding to the plurality of color resist blocks 103. As shown in FIG. 1, as the human eyes watch the display panel from the larger view angle, the light passing through one pixel unit 220 of the array substrate 200 will penetrate between the two color resist blocks 103 on the color film substrate 100 so that the light leakage happens between the adjacent pixel units, and the human eyes feel the color washout. Therefore, there is a need to provide a LTPS display panel to solve the aforesaid issue.

### SUMMARY OF THE INVENTION

An objective of the present invention is to provide a LTPS display panel, wherein the edge of the back matrix comprises a convex part which can better shade the light leakage between adjacent pixel units as watching in the large view angle, and can reduce the large view angle color washout to improve the display quality of the LTPS display panel.

Another objective of the present invention is to provide a manufacture method of the LTPS display panel, in which one halftone mask process is employed to form the black matrix, and the edge of the back matrix comprises a convex part which can better shade the light leakage between adjacent pixel units as watching in the large view angle, and thus, can reduce the large view angle color washout to improve the display quality of the LTPS display panel.

For realizing the aforesaid objectives, the present invention provides a LTPS display panel, comprising a color film substrate and an array substrate, wherein the color film substrate comprises a first substrate, a black matrix and a color resist layer located on the first substrate, and a flat layer located on the color resist layer;

wherein the black matrix comprises a plurality of black shading strips which are aligned horizontally and vertically, and the black shading strip comprises a flat part located on the first substrate and convex parts above two sides of the flat part; the color resist layer comprises a plurality of first, second and third color resist blocks which are separated by the black matrix; the array substrate comprises a second substrate, and a plurality of pixel units which are located on the second substrate and located corresponding to the plurality of the first, the second and the third color resist blocks.

A height of the convex part is smaller than a height of the flat part, and a width of the convex part is smaller than a width of the flat part.

The first substrate is a glass substrate; material of the black matrix is a black positive photoresist; material of the flat layer is organic photoresist.

The first, the second, the third color resist blocks are alignment combinations of red, green and blue resist blocks in arbitrary orders.

The pixel unit comprises a thin film transistor layer and pixel electrodes located on the thin film transistor layer, and the thin film transistor layer comprises a gate, a source, a drain and an active layer, and material of the active layer is low temperature poly-silicon.

The present invention further provides a manufacture method of a LTPS display panel, comprising steps of:

step 1, providing a first substrate, and coating black photoresist layer on the first substrate;

employing a halftone mask to implement exposure, development to the black photoresist layer to obtain a black matrix, wherein the black matrix comprises a plurality of black shading strips which are aligned horizontally and vertically, and the black shading strip comprises a flat part located on the first substrate and convex parts above two sides of the flat part;

step 2, sequentially coating first, second and third color resists on the black matrix and the first substrate, and employing a photolithographic process to pattern the same to obtain a plurality of first, second and third color resist blocks which are separated by the black matrix to form a color resist layer, and forming a flat layer on the color resist layer for manufacturing a color film substrate;

step 3, providing an array substrate, wherein the array substrate comprises a second substrate, and a plurality of pixel units which are located on the second substrate and located corresponding to the plurality of the first, the second and the third color resist blocks of the color resist layer;

aligning the array substrate and the color film substrate to form cell to obtain a LTPS display panel.

In the step 1, material of the black photoresist layer is black positive photoresist, and the halftone mask comprises a partially transparent area for defining the flat part, and a completely opaque area for defining the convex parts.

A height of the convex part is smaller than a height of the flat part, and a width of the convex part is smaller than a width of the flat part.

The first substrate is a glass substrate; material of the flat layer is organic photoresist; the first, the second, the third color resist blocks are alignment combinations of red, green and blue resist blocks in arbitrary orders.

The pixel unit comprises a thin film transistor layer and pixel electrodes located on the thin film transistor layer, and the thin film transistor layer comprises a gate, a source, a drain and an active layer, and material of the active layer is low temperature poly-silicon.

The present invention further provides a LTPS display panel, comprising a color film substrate and an array substrate, wherein the color film substrate comprises a first substrate, a black matrix and a color resist layer located on the first substrate, and a flat layer located on the color resist layer;

wherein the black matrix comprises a plurality of black shading strips which are aligned horizontally and vertically, and the black shading strip comprises a flat part located on the first substrate and convex parts above two sides of the flat part; the color resist layer comprises a plurality of first, second and third color resist blocks which are separated by the black matrix; the array substrate comprises a second substrate, and a plurality of pixel units which are located on the second substrate and located corresponding to the plurality of the first, the second and the third color resist blocks;

wherein a height of the convex part is smaller than a height of the flat part, and a width of the convex part is smaller than a width of the flat part;

wherein the first substrate is a glass substrate; material of the black matrix is a black positive photoresist; material of the flat layer is organic photoresist.

The benefits of the present invention are: in the LTPS display panel of the present invention, the edge of the back matrix comprises a convex part capable of ensuring that the light emitted from the pixel unit of the array substrate only penetrates through the color resist block corresponding to the pixel unit in the color film substrate, and no light leakage happens between adjacent pixel units and thus, can reduce the large view angle color washout to improve the display quality of the LTPS display panel. In the manufacture method of the LTPS display panel according to the present invention, one halftone mask process is employed to form the black matrix, and the edge of the back matrix comprises a convex part which can better shade the light leakage between adjacent pixel units as watching in the large view angle, and thus, can reduce the large view angle color washout to improve the display quality of the LTPS display panel.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a structure diagram of a LTPS display panel according to prior art;

FIG. 2 is a structure diagram of a LTPS display panel according to the present invention and also a diagram of the step 3 in a manufacture method of a LTPS display panel according to the present invention;

FIGS. 3-4 are diagrams of the step 1 in a manufacture method of a LTPS display panel according to the present invention;

FIG. 5 is a diagram of the step 2 in a manufacture method of a LTPS display panel according to the present invention.

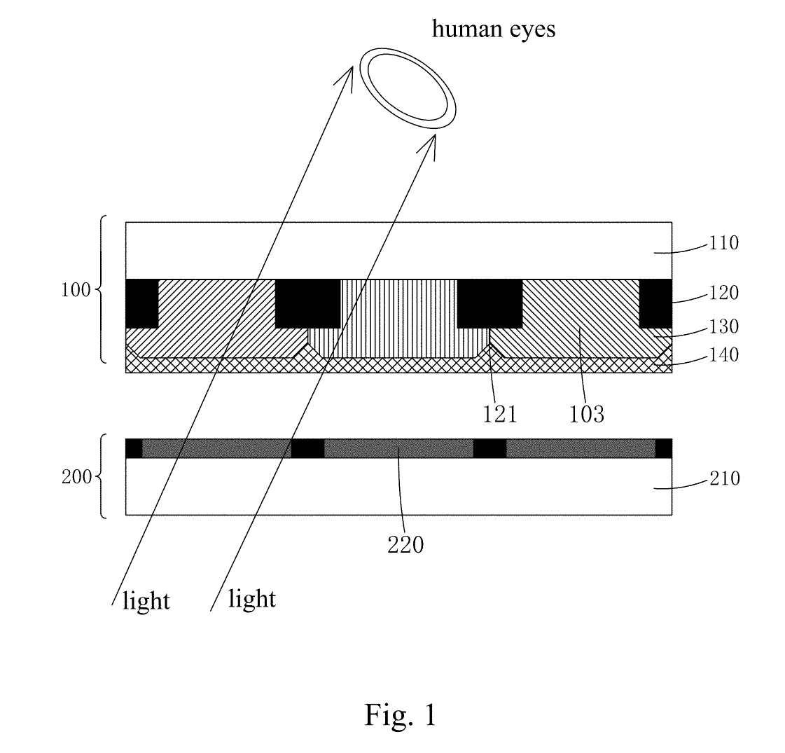

### DETAILED DESCRIPTION OF PREFERRED EMBODIMENTS

For better explaining the technical solution and the effect of the present invention, the present invention will be further described in detail with the accompanying drawings and the specific embodiments.

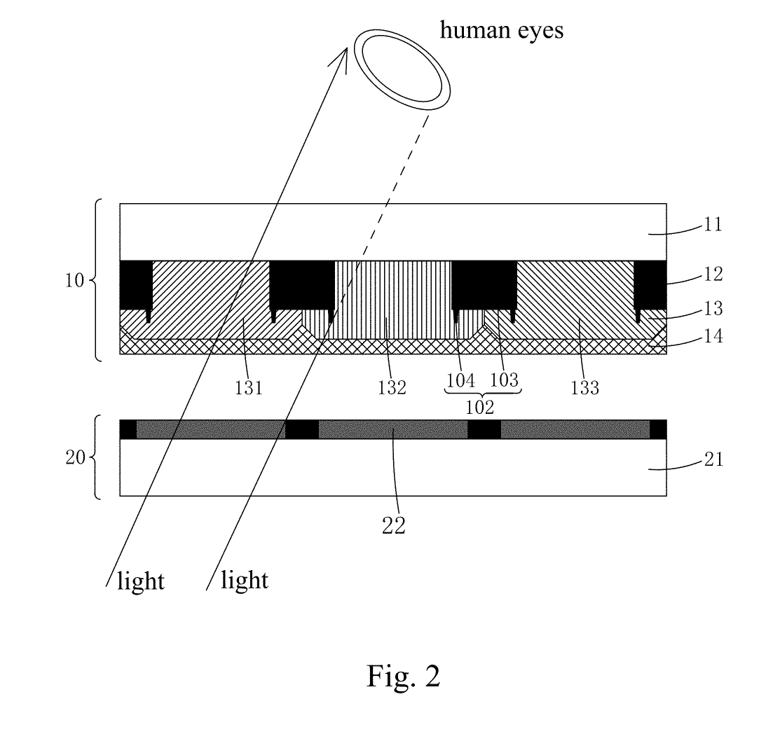

Please refer to FIG. 2. The present invention provides a LTPS display panel, comprising a color film substrate 10 and an array substrate 20, wherein the color film substrate 10 comprises a first substrate 11, a black matrix 12 and a color resist layer 13 located on the first substrate 11, and a flat layer 14 located on the color resist layer 13;

wherein the black matrix 12 comprises a plurality of black shading strips 102 which are aligned horizontally and vertically, and the black shading strip 102 comprises a flat part 103 located on the first substrate 11 and convex parts 104 above two sides of the flat part 103; the color resist layer 13 comprises a plurality of first, second and third color resist blocks 131, 132, 133 which are separated by the black matrix 12; the array substrate 20 comprises a second substrate 21, and a plurality of pixel units 22 which are located on the second substrate 21 and located corresponding to the plurality of the first, the second and the third color resist blocks 131, 132, 133.

Specifically, the first substrate 11 is a transparent substrate, and preferably is a glass substrate.

Specifically, material of the black matrix 12 is a black positive photoresist.

Specifically, a height of the convex part 104 is far smaller than a height of the flat part 103, and a width of the convex part 104 is far smaller than a width of the flat part 103.

Specifically, the first, the second, the third color resist blocks 131, 132, 133 are alignment combinations of red, green and blue resist blocks in arbitrary orders.

Specifically, material of the flat layer 14 is organic photoresist.

Specifically, the pixel unit 22 comprises a thin film transistor layer and pixel electrodes located on the thin film transistor layer, and the thin film transistor layer comprises a gate, a source, a drain and an active layer, and material of the active layer is low temperature poly-silicon.

As shown in FIG. 2, as the human eyes watch the LTPS display panel from the larger view angle, the edge of the black matrix 12 comprises a convex part 104, which can shade the light leakage between the adjacent pixel units in the large view angle and can ensure that the light emitted from the pixel unit 22 of the array substrate 20 only penetrates through the color resist block 131/132/133 corresponding to the pixel unit 22 in the color film substrate 10, and thus can reduce the large view angle color washout to improve the display quality of the LTPS display panel.

Please refer to FIGS. 2-5. The present invention further provides a manufacture method of a LTPS display panel, comprising steps of:

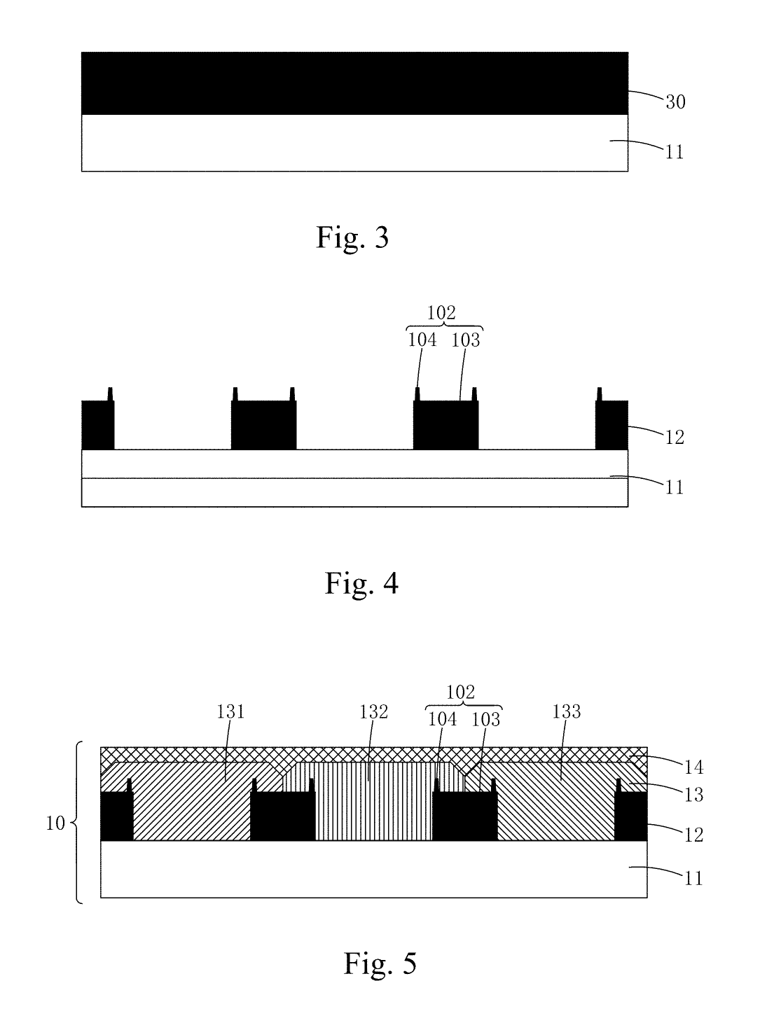

step 1, as shown in FIG. 3, providing a first substrate 11, and coating black photoresist layer 30 on the first substrate 11;

as shown in FIG. 4, employing a halftone mask to implement exposure, development to the black photoresist layer 30 to obtain a black matrix 12, wherein the black matrix 12 comprises a plurality of black shading strips 102 which are aligned horizontally and vertically, and the black shading strip 102 comprises a flat part 103 located on the first substrate 11 and convex parts 104 above two sides of the flat part 103.

Specifically, the first substrate 11 is a transparent substrate, and preferably is a glass substrate.

Specifically, material of the black photoresist layer 30 is black positive photoresist, and the halftone mask comprises a partially transparent area for defining the flat part 103, and a completely opaque area for defining the convex parts 104.

Specifically, a height of the convex part 104 is far smaller than a height of the flat part 103, and a width of the convex part 104 is far smaller than a width of the flat part 103. Thus, the volume of the convex part 104 is smaller, and has no influence to the coating and covering of the color resist on the black matrix 12.

step 2, as shown in FIG. 5, sequentially coating first, second and third color resists on the black matrix 12 and the first substrate 11, and employing a photolithographic process to pattern the same to obtain a plurality of first, second and third color resist blocks 131, 132, 133 which are separated by the black matrix 12 to form a color resist layer 13, and forming a flat layer 14 on the color resist layer 13 for manufacturing a color film substrate 10.

Specifically, the first, the second, the third color resist blocks 131, 132, 133 are alignment combinations of red, green and blue resist blocks in arbitrary orders.

Specifically, material of the flat layer 14 is organic photoresist.

step 3, as shown in FIG. 2, providing an array substrate 20, wherein the array substrate 20 comprises a second substrate 21, and a plurality of pixel units 22 which are located on the second substrate 21 and located corresponding to the plurality of the first, the second and the third color resist blocks 131, 132, 133 of the color resist layer 13;

aligning the array substrate 20 and the color film substrate 10 to form cell to obtain a LTPS display panel.

Specifically, the pixel unit 22 comprises a thin film transistor layer and pixel electrodes located on the thin film transistor layer, and the thin film transistor layer comprises a gate, a source, a drain and an active layer, and material of the active layer is low temperature poly-silicon.

In the aforesaid manufacture method of the LTPS display panel, one halftone mask process is employed to form the black matrix 12, and the edge of the back matrix 12 comprises a convex part 104 which can better shade the light leakage between adjacent pixel units as watching in the large view angle, and thus, can reduce the large view angle color washout to improve the display quality of the LTPS display panel.

In conclusion, in the LTPS display panel of the present invention, the edge of the back matrix comprises a convex part capable of ensuring that the light emitted from the pixel unit of the array substrate only penetrates through the color resist block corresponding to the pixel unit in the color film substrate, and no light leakage happens between adjacent pixel units and thus, can reduce the large view angle color washout to improve the display quality of the LTPS display panel. In the manufacture method of the LTPS display panel according to the present invention, one halftone mask process is employed to form the black matrix, and the edge of the back matrix comprises a convex part which can better shade the light leakage between adjacent pixel units as watching in the large view angle, and thus, can reduce the large view angle color washout to improve the display quality of the LTPS display panel.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A LTPS display panel, comprising a color film substrate and an array substrate, wherein the color film substrate comprises a first substrate, a black matrix and a color resist layer located on the first substrate, and a flat layer located on the color resist layer;
wherein the black matrix comprises a plurality of black shading strips which are aligned horizontally and vertically, and the black shading strip comprises a flat part located on the first substrate and convex parts above two sides of the flat part; the color resist layer comprises a plurality of first, second and third color resist blocks which are separated by the black matrix; the array substrate comprises a second substrate, and a plurality of pixel units which are located on the second substrate and located corresponding to the plurality of the first, the second and the third color resist blocks.

2. The LTPS display panel according to claim 1, wherein a height of the convex part is smaller than a height of the flat part, and a width of the convex part is smaller than a width of the flat part.

3. The LTPS display panel according to claim 1, wherein the first substrate is a glass substrate; material of the black matrix is a black positive photoresist; material of the flat layer is organic photoresist.

4. The LTPS display panel according to claim 1, wherein the first, the second, the third color resist blocks are alignment combinations of red, green and blue resist blocks in arbitrary orders.

5. The LTPS display panel according to claim 1, wherein the pixel unit comprises a thin film transistor layer and pixel electrodes located on the thin film transistor layer, and the thin film transistor layer comprises a gate, a source, a drain and an active layer, and material of the active layer is low temperature poly-silicon.

6. A manufacture method of a LTPS display panel, comprising steps of:
step 1, providing a first substrate, and coating black photoresist layer on the first substrate;
employing a halftone mask to implement exposure, development to the black photoresist layer to obtain a black matrix, wherein the black matrix comprises a plurality of black shading strips which are aligned horizontally and vertically, and the black shading strip comprises a flat part located on the first substrate and convex parts above two sides of the flat part;
step 2, sequentially coating first, second and third color resists on the black matrix and the first substrate, and employing a photolithographic process to pattern the same to obtain a plurality of first, second and third color resist blocks which are separated by the black matrix to form a color resist layer, and forming a flat layer on the color resist layer for manufacturing a color film substrate;
step 3, providing an array substrate, wherein the array substrate comprises a second substrate, and a plurality of pixel units which are located on the second substrate and located corresponding to the plurality of the first, the second and the third color resist blocks of the color resist layer;
aligning the array substrate and the color film substrate to form cell to obtain a LTPS display panel.

7. The manufacture method of the LTPS display panel according to claim 6, wherein in the step 1, material of the black photoresist layer is black positive photoresist, and the halftone mask comprises a partially transparent area for defining the flat part, and a completely opaque area for defining the convex parts.

8. The manufacture method of the LTPS display panel according to claim 6, wherein a height of the convex part is smaller than a height of the flat part, and a width of the convex part is smaller than a width of the flat part.

9. The manufacture method of the LTPS display panel according to claim 6, wherein the first substrate is a glass substrate; material of the flat layer is organic photoresist; the first, the second, the third color resist blocks are alignment combinations of red, green and blue resist blocks in arbitrary orders.

10. The manufacture method of the LTPS display panel according to claim 6, wherein the pixel unit comprises a thin film transistor layer and pixel electrodes located on the thin film transistor layer, and the thin film transistor layer comprises a gate, a source, a drain and an active layer, and material of the active layer is low temperature poly-silicon.

11. A LTPS display panel, comprising a color film substrate and an array substrate, wherein the color film substrate comprises a first substrate, a black matrix and a color resist layer located on the first substrate, and a flat layer located on the color resist layer;
wherein the black matrix comprises a plurality of black shading strips which are aligned horizontally and vertically, and the black shading strip comprises a flat part located on the first substrate and convex parts above two sides of the flat part; the color resist layer comprises a plurality of first, second and third color resist blocks which are separated by the black matrix; the array substrate comprises a second substrate, and a plurality of pixel units which are located on the second substrate and located corresponding to the plurality of the first, the second and the third color resist blocks;
wherein a height of the convex part is smaller than a height of the flat part, and a width of the convex part is smaller than a width of the flat part;
wherein the first substrate is a glass substrate; material of the black matrix is a black positive photoresist; material of the flat layer is organic photoresist.

12. The LTPS display panel according to claim 11, wherein the first, the second, the third color resist blocks are alignment combinations of red, green and blue resist blocks in arbitrary orders.

13. The LTPS display panel according to claim 11, wherein the pixel unit comprises a thin film transistor layer and pixel electrodes located on the thin film transistor layer, and the thin film transistor layer comprises a gate, a source, a drain and an active layer, and material of the active layer is low temperature poly-silicon.
